(19) United States
(12) Patent Application Publication
(10) Pub. No.: US 2015/0326960 A1
(43) Pub. Date: Nov. 12, 2015

(54) Miniature low profile speaker and case assembly

(71) Applicant: Prescient Audio Mfg LLC, Rockford, IL (US)

(72) Inventors: Paul Niedermann, Rockford, IL (US); Karl R. Schmitt, Rockford, IL (US)

(21) Appl. No.: 14/544,806

(22) Filed: Feb. 18, 2015

Related U.S. Application Data
(60) Provisional application No. 61/941,208, filed on Feb. 18, 2014.
(60) Provisional application No. 62/112,535, filed on Feb. 5, 2015.

(51) Int. Cl. H04R 1/02; H03F 3/183; H04R 1/08; H04R 5/00; H04R 3/00

(52) U.S. Cl. CPC H04R 1/02; H04R 5/00; H04R 3/002; H04R 1/08; H03F 3/183; H03F 2200/03

(57) ABSTRACT

A low-profile speaker and case assembly includes a case configured to house a handheld electronic device, a digital signal processor attached to an interior surface of the case and coupled to an amplifier. The digital processor is configured to receive audio signals from the handheld electronic device, and to output audio signals to the amplifier. A battery is attached to an interior surface of the case. The battery supplies power to the digital signal processor and amplifier, and a low-profile speaker driver arranged within the case. The low-profile speaker is connected to the amplifier and powered by the battery to produce high quality audio outputs.

### RELATED APPLICATIONS (PRIORITY CLAIM)

This application claims the benefit of U.S. Provisional Application Ser. No. 61/941,208, filed Feb. 18, 2014, and U.S. Provisional Application Ser. No. 62/112,535, filed Feb. 5, 2015, both of which are incorporated herein by reference in their entirety.

### FIELD OF THE INVENTION

This invention generally relates to speakers, such as those used in a variety of consumer electronics and audio systems.

### BACKGROUND OF THE INVENTION

Generally, the speakers used in handheld consumer electronic devices, such as smartphones and tablet computers, have limited functionality. The speaker typically have high resonance frequencies (e.g., greater than 700 hertz) resulting in a tinny, or small, sound that quickly degrades with distance from the speaker and provides poor low-frequency, or bass, response. Most high traffic areas, i.e., restaurants, taverns, sporting events and the like, have background noise of between 80 db and 85 db making it difficult or impossible to hear cell or smart phone transmissions.

There is a need for a miniature speaker with improved bass response and overall audio quality. Embodiments of the present invention provide such a miniature speaker. These and other advantages of the invention, as well as additional inventive features, will be apparent from the description of the invention provided herein.

### BRIEF SUMMARY OF THE INVENTION

In one aspect, embodiments of the invention provide a low-profile speaker having a low-profile frame, and a first magnet assembly disposed in the low-profile frame. The first magnet assembly has a first cage and a plurality of magnets disposed in the first cage. The low-profile speaker also includes a support assembly having a cone and a support ring attached to the cone, and a voice coil attached to the support ring. The support ring and voice coil are suspended in relatively close proximity to the magnet assembly such that the support ring and voice coil oscillate in response to electrical signals in the voice coil.

In a particular embodiment, the plurality of magnets is disposed in individual pockets around the circumference of the cage. The first magnet assembly, second magnet assembly, and bottom plate may be annular or rectangular. In a further embodiment, the voice coil is a metal wire wound around the support ring, and the first magnet assembly and the voice coil are concentric about a central axis of the frame. The magnet assembly is disposed along an interior perimeter surface of the frame. The voice coil may have a larger diameter than the magnet assembly in certain embodiments, and a smaller diameter than the magnet assembly in alternate embodiments.

In another aspect, embodiments of the invention provide a low-profile speaker having a low-profile frame, and a first magnet assembly disposed in the low-profile frame. The first magnet assembly has a first cage and a first solid ring of magnetic material, such as neodymium or samarium-cobalt for example, disposed in the first cage. In an alternate embodiment, the first magnet assembly is a solid ring of composite magnetic material. The low-profile speaker also includes a support assembly having a cone and a support ring attached to the cone, a voice coil attached to the support ring. The support ring and voice coil are suspended in relatively close proximity to the magnet assembly such that the support ring and voice coil oscillate in response to electrical signals in the voice coil.

In the alternative embodiment of the invention referenced above, the first solid ring of composite magnetic material includes a plurality of fragments of magnetic material suspended in an epoxy. The poles of the plurality of fragments are aligned prior to the hardening of the epoxy. In a particular embodiment, the fragments of magnetic material include fragments of neodymium or samarium-cobalt.

The low-profile speaker may further include a surround attached to the low-profile frame and to the support assembly. The surround is made of a resilient material and has an outer perimeter portion, and inner perimeter portion, and an arched portion that joins the inner and outer perimeter portions. The outer perimeter portion is attached to the low-profile frame, and the inner perimeter portion is attached to a cone. The cone is flat or concave with respect to the low-profile frame. In particular embodiments, the surround is made from an elastomeric material.

In particular embodiment of the low-profile speaker, the first magnet assembly has a pole piece attached to a bottom surface of the first solid ring of magnetic material. The pole piece has a horizontal portion and a vertical portion. A top plate is attached to a top surface of the first solid ring of magnetic material. A gap between the top plate and the vertical portion accommodates the support ring and voice coil.

Further, the low-profile speaker may include a second magnet assembly disposed in the low-profile frame. The second magnet assembly has a second cage and a second solid ring of magnetic material disposed in the second cage. The second magnet assembly is concentric with, and has a smaller width or diameter than, the first magnet assembly. The first magnet assembly and the second magnet assembly are connected by a bottom plate attached to bottom surfaces of the first and second solid rings of magnetic material in the first and second magnet assemblies. In embodiments, a first top plate is attached to a top surface of the first solid ring of magnetic material, and a second top plate is attached to a top surface of the second solid ring of magnetic material. A gap between the first top plate and the second top plate accommodates the support ring and voice coil.

In an alternate embodiment, a first solid ring of composite magnetic material includes magnetic fragments whose individual magnetic poles are aligned such the first solid ring of magnetic material effectively has a single north pole and a single south pole. Further, a second voice coil is wound onto the support ring, the voice coil and the second voice coil being in close proximity to opposite poles of the first solid ring of magnetic material. The ratio of the width or diameter of the low-profile speaker to the depth of the speaker is greater than 5, in some embodiments, and greater than 20 in more particular embodiments.

In yet another aspect, embodiments of the invention provide a low-profile speaker that includes a frame having a stepped portion. The stepped portion has a plurality of openings and there is a plurality of magnets disposed in the plurality of openings. A voice coil is supported by a cone disc that fits within the stepped frame, and the voice coil is suspended in relatively close proximity to the plurality of magnets. Together, a top plate and pole piece hold the plurality of magnets in the frame. The top plate and pole piece are assembled such that the voice coil can oscillate in a gap between the top plate and pole piece.

A particular low-profile speaker includes a surround made from a resilient material, the surround having an outer perimeter portion and an inner perimeter portion, the outer perimeter portion being attached to the frame, the inner perimeter portion attached to the cone disc such that the cone disc and voice coil are suspended between the gap between the top plate and pole piece.

In an embodiment, the cone disc is made from one of aluminum and a transparent material, but other rigid materials and composites (i.e., structural foam, graphite, and glass filled discs) are considered for proper suspension; some of the material being market-segment-specific. A perimeter portion of the frame may include a plurality of openings. In a further embodiment, the pole piece has a horizontal portion and a vertical portion, and the aforementioned gap is between the vertical portion and an inner perimeter surface of the top plate.

In yet another aspect, embodiments of the invention provide a low-profile speaker and case assembly includes a case configured to house a handheld electronic device, a digital signal processor attached to an interior surface of the case and coupled to an amplifier, a battery attached to an interior surface of the case, the battery supplying power to the digital signal processor and amplifier, and a low-profile speaker driver arranged within the case. The low-profile speaker is connected to the amplifier and powered by the battery. A particular embodiment of the invention includes a case assembly with a connector adapted for the USB port (or proprietary port) of a smart device as the means to connect the case to smart device for digital signal processing and digital to analog power and processing. In more particular embodiment, the case assembly is configured to supply power, via the battery, to operate or charge the handheld electronic device. In some embodiments, this function may only be executed when the charge on the handheld electronic device battery drops below some threshold level.

In a particular embodiment, the low-profile speaker includes an integral voice coil and cone assembly and has a resonance frequency ranging from 100 hertz to 200 hertz. In a further embodiment, the low-profile speaker has a back volume ranging from 70 to 100 cubic centimeters, and has a ratio of maximum excursion to driver depth ranges from 0.125 to 0.29.

In a certain embodiment, the low-profile speaker includes an integral voice coil and cone assembly and has a fundamental frequency ranging from human voice tones, i.e., 85 Hz to 255 Hz. In a further embodiment, the low-profile speaker has adequate back volume for maximum driver excursion.

In a certain embodiment of the invention, the digital signal processor is configured to detect a level of ambient noise surrounding the case assembly, and further configured to automatically set the volume from the low-profile speaker at a level above that of the ambient noise. Furthermore, the low-profile speaker may be configured to provide sound to complement sound provided by a speaker in the handheld electronic device, such that the combined speakers produce a full range of frequency cross-over up to 20 kilohertz.

Other aspects, objectives and advantages of the invention will become more apparent from the following detailed description when taken in conjunction with the accompanying drawings.

### BRIEF DESCRIPTION OF THE DRAWINGS

The accompanying drawings incorporated in and forming a part of the specification illustrate several aspects of the present invention and, together with the description, serve to explain the principles of the invention. In the drawings:

FIG. 1 is a perspective view of a low-profile speaker, constructed in accordance with an embodiment of the invention;

FIG. 2 is a cross-sectional view of the low-profile speaker of FIG. 1, constructed in accordance with a particular embodiment of the invention;

FIG. 3 is a cross-sectional view of the low-profile speaker of FIG. 2, shown from a different angle and offering a perspective view of the low-profile speaker;

FIG. 4 is a cross-sectional view of a low-profile speaker, constructed in accordance with an alternate embodiment of the invention;

FIG. 5 is a cross-sectional view of the low-profile speaker of FIG. 4, shown from a different angle and offering a perspective view of the low-profile speaker;

FIG. 6 is a cross-sectional view of the low-profile speaker including a rear baffle and second surround, in accordance with an embodiment of the invention;

FIGS. 7 and 8 are perspective views of a rectangular low-profile speaker, constructed in accordance with an embodiment of the invention;

FIG. 9 is a perspective view of the low-profile speaker of FIG. 1 assembled in a square housing;

FIG. 10 is a cross-sectional view of a low-profile speaker, constructed in accordance with an alternate embodiment of the invention;

FIG. 11 is an exploded isometric view of a low-profile speaker, constructed in accordance with an embodiment of the invention;

FIG. 12 is an isometric view of the low-profile speaker of claim 11, including a frame with a plurality of openings;

FIG. 13 is a perspective view of a case assembly which is in accordance with an embodiment of the present invention, wherein a low profile speaker is provided on a back of the case assembly;

FIG. 14 is a cross-sectional view of the case shown in FIG. 13;

FIG. 15 is a perspective view of a case assembly which is in accordance with an embodiment of the present invention, wherein a low profile speaker is provided on a front of the case assembly;

FIG. 16 is a cross-sectional view of the case shown in FIG. 15;

FIG. 17 is a perspective view of a case assembly which is in accordance with an embodiment of the present invention, wherein two low profile speakers are provided on a front of the case assembly;

FIG. 18 is a cross-sectional view of the case shown in FIG. 17;

FIG. 19 is a cross-sectional view of one version of the low profile speaker which can be used in connection with the case assemblies shown in FIGS. 13-18;

FIG. 20 is a cross-sectional view of another version of the low profile speaker which can be used in connection with the case assemblies shown in FIGS. 13-18;

FIG. 21 is a circuit block diagram which can relate to any of the case assemblies shown in FIGS. 13-18; and

FIG. 22 is an exemplary circuit diagram which relates specifically to the case assembly shown in FIGS. 17 and 18.

While the invention will be described in connection with certain preferred embodiments, there is no intent to limit it to those embodiments. On the contrary, the intent is to cover all alternatives, modifications and equivalents as included within the spirit and scope of the invention as defined by the appended claims.

### DETAILED DESCRIPTION OF EMBODIMENTS

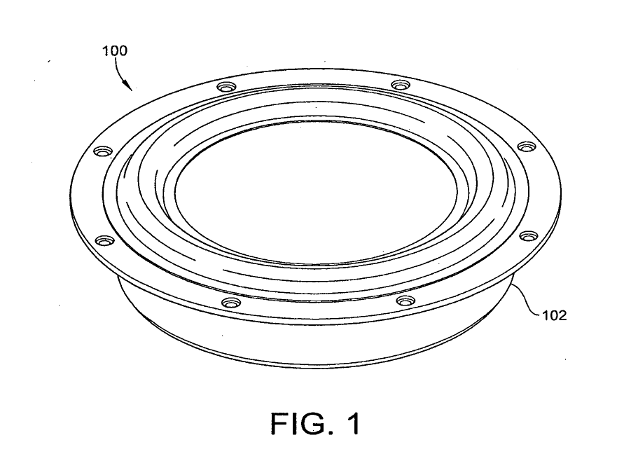

FIG. 1 shows a perspective view of a low-profile speaker 100 constructed in accordance with an embodiment of the invention. In a particular embodiment, the low-profile speaker 100 of FIG. 1 is a sub-woofer, configured to provide low-frequency sound. In many conventional speaker systems, the subwoofer (or simply “sub”) is typically between 8″ and 21″ in diameter, which is dedicated to the reproduction of low-pitched audio frequencies (i.e., the “bass”). The typical frequency range for a subwoofer is about 20-200 Hz for consumer products, below 100 Hz for professional live sound, and often below 80 Hz for the most advanced subwoofers.

In the embodiment of FIG. 1, the low-profile speaker 100 includes a substantially disk-shaped, low-profile frame 102 which includes a cup-like portion 104 in the disk-shaped interior, and a flanged portion 106 at the periphery of the disk-shaped frame 102 attached to the top rim of the cup-like portion 104. In at least one embodiment, the frame 102 is shaped and formed from a single malleable, yet sufficiently rigid, material, or molded from a suitably rigid material. However, in alternate embodiments, the frame 102 is assembled from separate components.

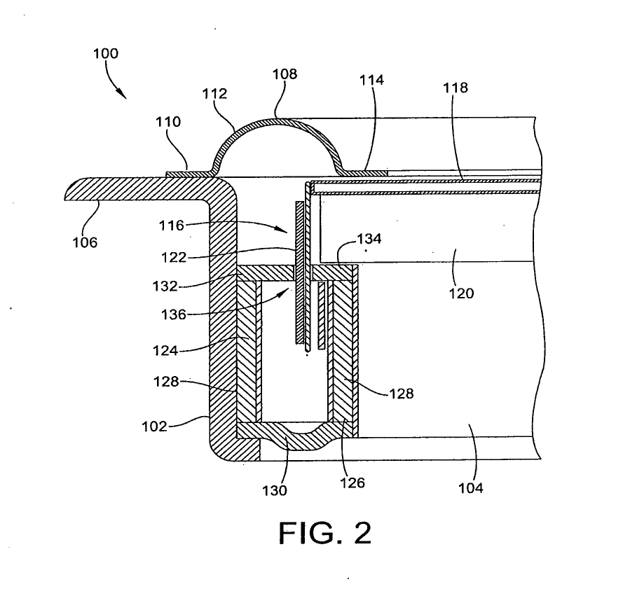

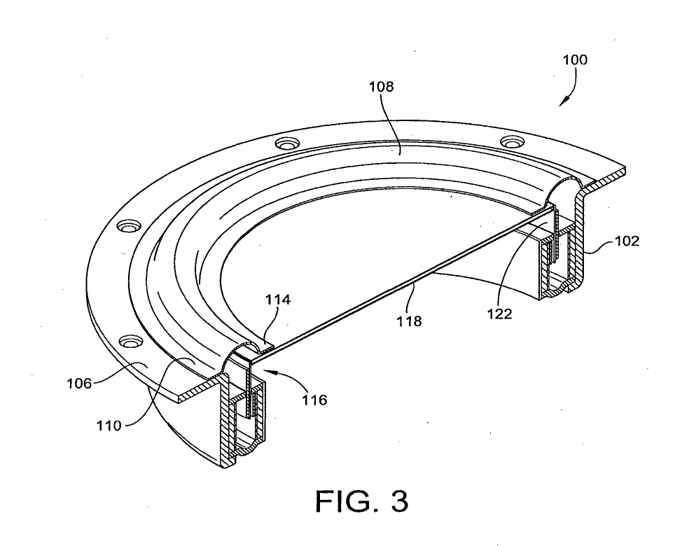

On a surface of the flanged portion 106, a surround 108 is attached. The surround 108 is an annular component, made from a resilient material, for example an elastomer, such as butyl rubber. In a particular embodiment, the annular surface of the surround 108 is arched, with a first flat portion 110, or outer flat portion, of the arch 112 and a second flat portion 114, or inner flat portion, of the arch 112, such that the apex of the arch 112 forms a circle roughly at the midway point between the inner diameter and the outer diameter of the annular surround 108. The first flat portion 110 of the surround 108 is attached to the surface of the flanged portion 106 of the frame 102. The second flat portion 114 of the surround 108 extends radially into the cup-like portion 104 and, as will be shown in FIGS. 2 and 3, is attached to a support assembly 116 that includes a cone 118 and a support ring 120. With respect to embodiments of the invention, the “cone” is not necessarily conical, and may have various shapes including, but not limited to, flat, concave, convex, and conical. In conventional speakers, the support ring 120 is more typically referred to as a former or voice coil former.

FIGS. 2 and 3 show a cross-sectional view of the low-profile speaker 100. The second flat portion 114 of the surround 108 is attached to a flat, circular cone 118. The circular cone 118 is, in turn, attached to the support ring 120, which supports a voice coil 122. In embodiments of the invention, the voice coil 122 comprises wire made from aluminum, copper, alloys of these metals or from some other suitable material. The wire is wound around the support ring 120. The support ring 120 may be made from plastic, or some other lightweight but rigid material suitable for supporting the voice coil 122. The embodiment of FIG. 2 shows a first magnet assembly 124 and second magnet assembly 126.

In at least one embodiment, each magnet assembly 124, 126 comprises an annular cage for holding a plurality of magnets 128. Typically, the annular cage is configured to evenly space the plurality of magnets 128 around the circumference of the frame 102. The first and second magnet assemblies 124, 126 shown are annular, the first magnet assembly 124 having a greater diameter that the second magnet assembly 126. The frame 102 may be constructed to hold the annular cage in the proper position. In certain embodiments, the magnets 128 are placed side by side in pockets around the entire circumference of the annular cage.

The first magnet assembly 124, or outer magnet assembly, is located substantially along an inner wall of the cup-like portion 104 of the frame 102 in spaced relation to an outer diameter surface of the voice coil 122 and support ring 120. The second magnet assembly 126, or inner magnet assembly, is located in spaced relation to an inner diameter surface of the voice coil 122 and support ring 120. In at least one embodiment, the magnet assemblies 124, 126 each include magnets 128 made from rare earth metals such as neodymium or samarium cobalt. The strength of these magnets 128 allows for the construction of smaller, lighter magnet assemblies than typically found in conventional speakers. In certain embodiments, the magnets 128 may be curved rather than flat, or may have a shape other than rectangular.

An annular bottom plate 130 connects the bottom surfaces of the magnets 128 in the outer magnet assembly 124 to the bottom surfaces of the magnets 128 in the inner magnet assembly 126. In conventional speakers, this bottom plate 130 is sometimes referred to as a pole piece. In at least one embodiment, the annular bottom plate 130 is arched away from the magnets 128 to create more space for the voice coil 122 to move between the magnet assemblies 124, 126. There are two annular top plates. A first top plate 132, or outer top plate is attached to the top surfaces of the magnets 128 in the outer magnet assembly 124. The second top plate 134, or inner top plate, is attached to the top surfaces of the magnets 128 in the inner magnet assembly 126.

As seen in FIG. 2, the first and second magnet assemblies 124, 126, along with the bottom and top plates 130, 132, 134 form a rectangular or boxlike cross-section with an opening therein for the voice coil 122. The opening is more accurately described as an annular gap 136 between the outer first top plate 132 and the inner second top plate 134. This annular gap, typically referred to as the magnetic gap 136, is spaced just wide enough to allow the annular voice coil 122 and attached support ring 120 to move back and forth in the magnetic gap 136 without contacting either of the top plates 132, 134. Thus, when the low-profile speaker 100 is not operating, the voice coil 122 and support ring 120 are suspended, via their connection to the cone 118 and surround 108, in the magnetic gap 136 between the two annular top plates 132, 134 with at least a portion of the voice coil 122 between the two magnet assemblies 124, 126. In an embodiment, the bottom plate and two top plates are made from a ferromagnetic material.

By making the magnet assemblies 124, 126 annular and spacing the voice coil 122 in relation to the magnet assemblies 124, 126, it is possible to construct a subwoofer having a significantly reduced depth as compared to conventional subwoofers. The annular inner and outer magnet assemblies 124, 126 are substantially concentric. During operation, the inner and outer magnet assemblies 124, 126, along with the top plates 132, 134 and bottom plate 130, generate a magnetic field sufficient to drive the voice coil 122 and attached support ring 120 with little distortion of low-frequency sound, even within the shallow depth of the low-profile speaker 100. Thus, in embodiments of the low-profile speaker 100, the ratio of the diameter or width of the low-profile frame 102 to the thickness or depth of the frame 102 will range from approximately seven to 25, and, in some embodiments, may be greater than 25. In the context of this application, the term “low-profile” refers to speakers and speaker components having ratios of width to depth in the aforementioned range.

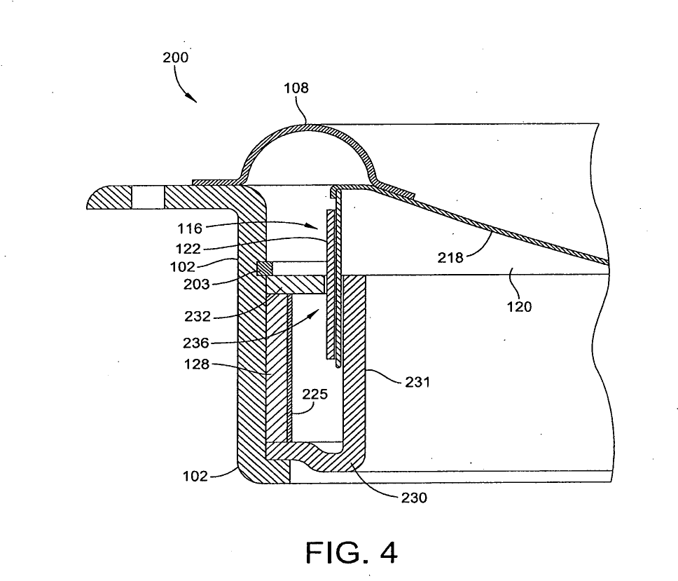

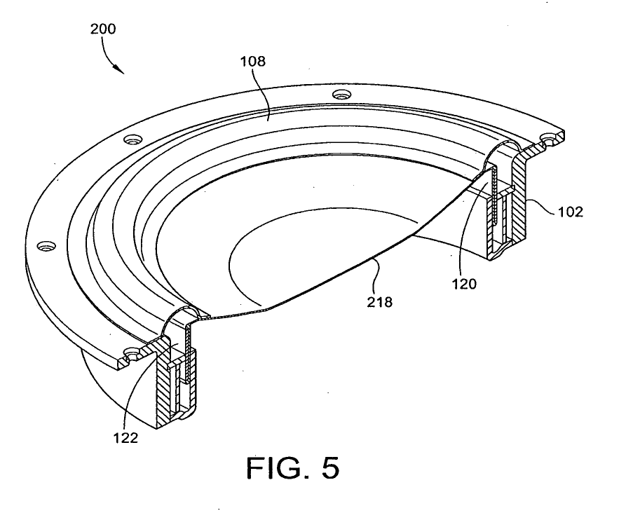

In a particular embodiment of the invention which is also illustrated by FIGS. 2 and 3, a magnet assembly is employed that includes a solid ring of magnetic material, such as neodymium or samarium-cobalt. In an alternate embodiment, the solid ring is a composite magnetic material having numerous fragments of magnetic material, for example neodymium or samarium-cobalt, suspended in a liquid epoxy. The liquid epoxy is formed into a ring and the poles of the magnetic fragments are aligned so that the ring has essentially a single north pole and a single south pole. The epoxy is then cured to form a rigid magnetic ring. The solid ring of magnetic material can be attached to the top plates 132 and bottom plate 130 of ferromagnetic material and assembled into the speaker frame 102, as shown in the embodiments of FIGS. 4 and 5, described below. In a further embodiment, two solid magnetic rings 124, 126 of slightly different diameter are used to represent the magnets 128 on each side of the voice coil 122, as shown in the embodiments of FIGS. 2 and 3. Typically, the solid magnetic rings 124, 126 are arranged concentrically, and the bottom plate 130 of ferromagnetic material is assembled to both magnetic rings 124, 126 joining the rings 124, 126 at a bottom edge as shown in FIGS. 2 and 3. In an embodiment, each magnetic ring 124, 126 has its own top plate 132, 134 of ferromagnetic material arranged such that a magnetic gap 136 is formed to allow for movement of the suspended voice coil 122 therein, as shown in FIGS. 2 and 3.

FIGS. 4 and 5 show a cross-sectional view of an alternate embodiment of the low-profile speaker 200. In this alternate embodiment, the frame 102, surround 108, voice coil 122, and support ring 122 are the similar or identical to the components in the embodiment of FIGS. 2 and 3. However, the alternate embodiment has only one magnetic assembly 224 having a cage 225 and a plurality of rectangular magnets 128. Further, the cone 218 in this embodiment is concave, curved into the cup-like portion 104 of frame 102, instead of being flat like cone 118 of FIGS. 1-3. In the embodiment of FIGS. 4 and 5, the magnetic assembly 224 is located along the inner wall of the cup-like portion 104 of the frame 102 facing the outer diameter surface of the voice coil 122 and support ring 120. In some embodiments, a snap ring 203, or similar device, is used to secure the magnet assembly 224 in place in the frame 102. A top plate 232 is attached to a top surface of the magnets 128 in the magnet assembly 224, and extends horizontally for a short distance from the tops of the magnets 128. A bottom plate or pole piece 230 is attached to the bottom surfaces of the magnets 128 in the magnet assembly 224. The pole piece 230 extends horizontally from the magnet 128 under the annular voice coil 122, and a vertical portion 231 extends up in spaced relation to the inner diameter surface of the voice coil 122 and support ring 120.

In this arrangement, there is a magnetic gap 236 between the top plate 232 and the vertical portion 231 of the pole piece 230. In at least one embodiment, top plate 232 and the pole piece 230 are made from a ferromagnetic material. In this way, the voice coil 122 and support ring 120 are suspended in the magnetic gap 236 between the top plate 232 and vertical portion 231 of the pole piece 230, and also between the magnet assembly 224 and the vertical portion 231 of the pole piece 230.

During operation, the magnet assembly 224 and pole piece 230 generate a magnetic field sufficient to drive the voice coil 122 and attached support ring 120, even within the shallow depth of the low-profile speaker 200, with little distortion of low-frequency sound. Supported in suspension by the attachment to the surround 108, the support assembly 116 oscillates, or moves back and forth in the space between the magnet assembly 224 and vertical portion 231 of the pole piece 230.

In an alternate embodiment of the invention of FIGS. 4 and 5, the magnetic assembly 224 is positioned inside of the voice coil 122 and support ring 120 such that the magnets 128 face the inner diameter face of the voice coil 122 and support ring 120. In this embodiment, the pole piece 230 is attached to the bottom surfaces of the magnets 128 as in the above-described embodiment. The vertical portion 231 extends under the annular voice coil 122 and up in spaced relation to the outer diameter surface of the voice coil 122 and support ring 120. As in the example above, the pole piece 230 is made from a ferromagnetic material. Also, as in the above example, the voice coil 122 and support ring 120 are suspended between the magnet assembly 224 and the vertical portion 231 of the pole piece 230. Further, the voice coil in this further embodiment oscillates, or moves back and forth in the magnetic gap 236 between the magnet assembly 224 and vertical portion 231 of the pole piece 230.

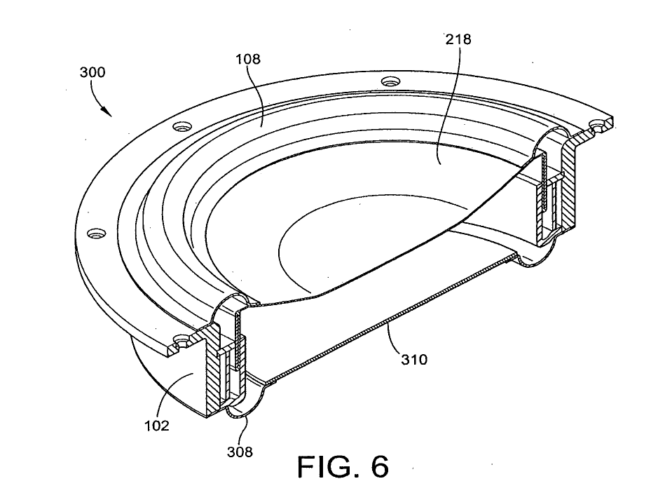

FIG. 6 illustrates an embodiment of the low-profile speaker 300, which includes the surround 108, concave cone 218, and a rear baffle 308 attached to the frame 102. Rear baffle 308 is structurally similar to the surround 108, being made of a resilient elastomeric material such as butyl rubber. The rear baffle 108 allows for some movement of a rear portion 310 of the frame 102. In this configuration, the low-profile speaker 300 performs similarly to an isobaric speaker, in that the frequency response is lowered. Typically, the term “isobaric speaker” refers to the operational characteristics of the use of at least two woofers, or bass drivers, in a loudspeaker unit. The use of isobaric loading in a speaker system in practical terms is to lower the bass frequency response.

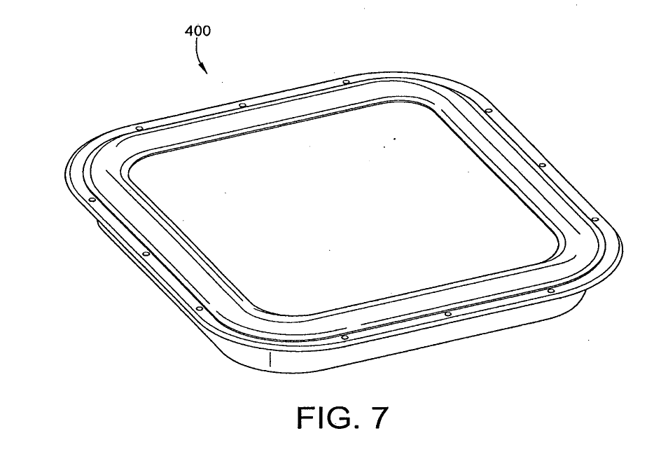

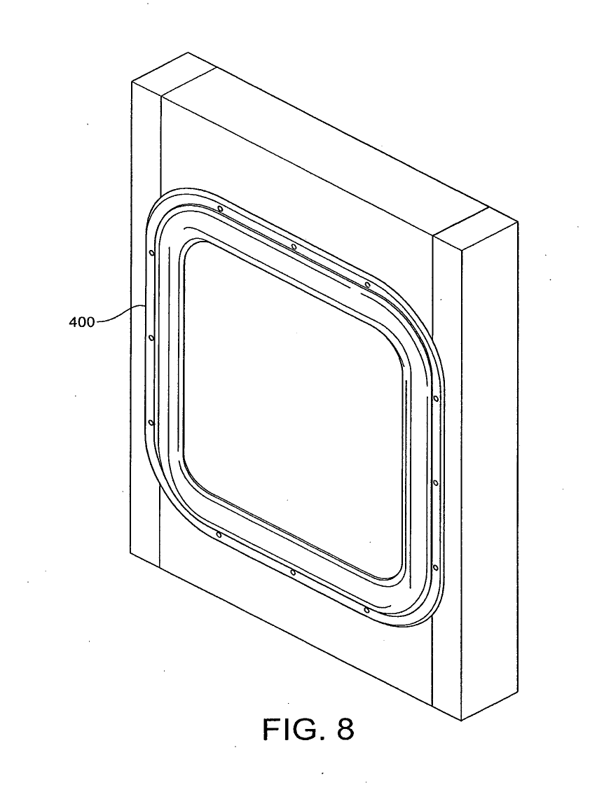

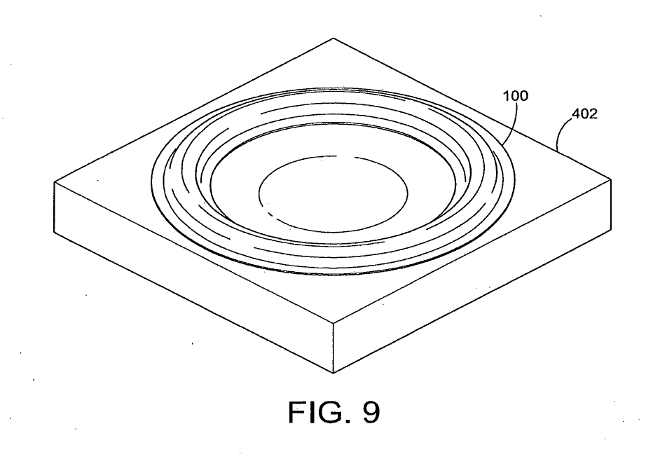

FIGS. 7 and 8 show perspective views of a rectangular low-profile speaker 400, constructed in accordance with an embodiment of the invention. The components and inner working of the rectangular speaker 400 are similar or identical to those in the embodiment described above, except that the frame, surround, magnet assembly, voice coil, and support ring, and cone are rectangular rather than circular. Of course, in alternate embodiments of the invention, the low-profile speaker can be constructed in other shapes such as oval, hexagonal, octagonal, triangular, or in any of a variety of shapes. However, this can also be accomplished using the round low-profile speaker 100 installed in a rectangular box 402, as illustrated in FIG. 9.

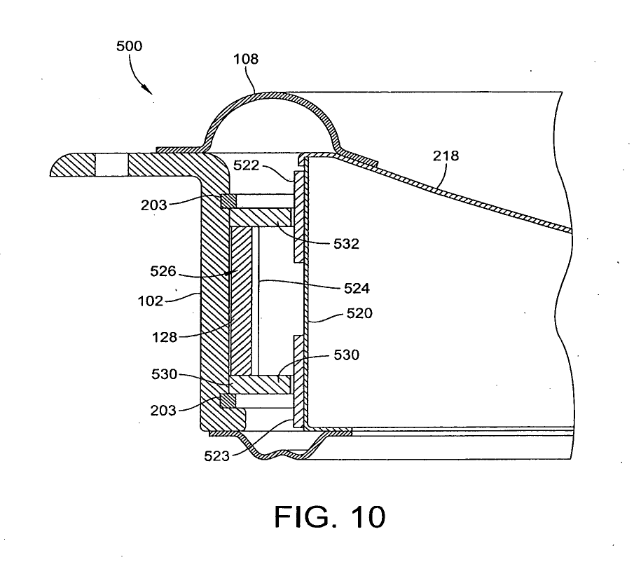

FIG. 10 is a plan view of a low-profile speaker 500 having a dual-coil configuration, in accordance with an embodiment of the invention. In this embodiment, the magnet assembly includes an annular cage 524 configured to hold either a plurality of relatively small magnets 128 in a magnet assembly 526, a solid ring of magnetic material, or a solid ring of composite magnetic material in a magnet assembly 526 such as described above. In a particular embodiment, the magnet assembly 526 is in contact, or in close proximity to the frame 102. A top plate 532 and bottom plate 530 of approximately equal size are attached, respectively, to the top edge and bottom edge of the magnet 128.

The top and bottom plates 532, 530 are made from a ferromagnetic material and project radially inward from the magnet 128 and perimeter of the frame 102. A first voice coil 522 is situated in relatively close proximity to the top plate 532, while a second voice coil 523 is situated in relatively close proximity to the bottom plate 530. In at least one embodiment, the two voice coils 522, 523 are wound in opposite directions around the support ring 520. In an alternate embodiment, the two voice coils 522, 523 are wound in the same direction, but the terminal ends of the first voice coil 522 are connected to a power supply (not shown) such that the polarities are the reverse of the terminal ends of the second voice coil 523. In this fashion, the voice coils 522, 523, which are located in proximity to opposite poles of the magnets 128, move in the same direction in response to the electrical signals that drive the speaker 500.

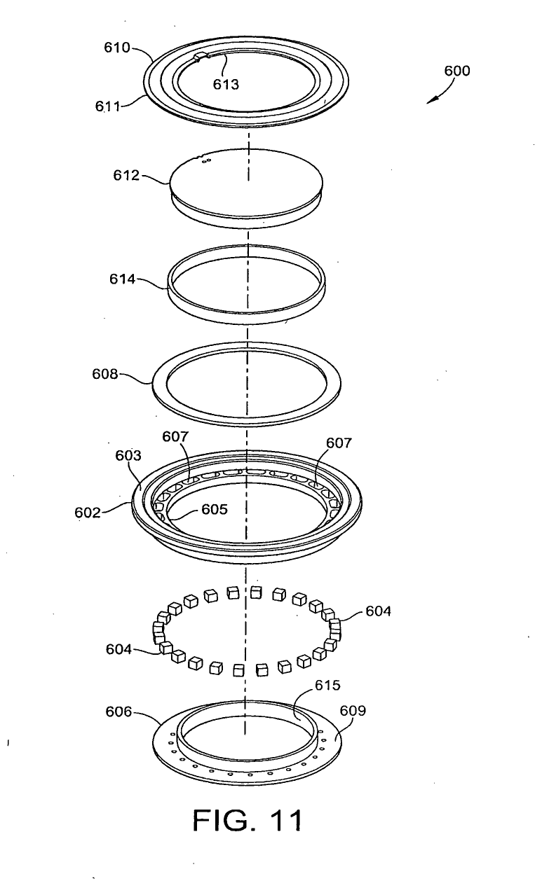

FIG. 11 is an exploded isometric view of a low-profile speaker 600, constructed in accordance with an embodiment of the invention. Low-profile speaker 600 has an annular stepped frame 602 with a flange 603 and an interior step 605. Around the circumference of the interior step 605, there is a plurality of rectangular openings 607 to hold a plurality of magnets 604. Though held in place by the rectangular openings 607, each of the plurality of magnets 604 is supported on the bottom by a pole piece 606 and supported on the top by a top plate 608. The pole piece e 606 includes an annular horizontal portion 609, and an annular vertical portion 615. In the embodiment shown, the magnets 604 are cube-shaped, though, in alternate embodiments, the magnets may have shapes other than cubed, and the rectangular openings 607 may be other than rectangular. In a further embodiment, the plurality of magnets 604 may be replaced by a solid ring of magnetic material, such as neodymium or samarium-cobalt for example, or by a composite magnetic material, as described above.

The pole piece and top plate 606, 608 are made from a ferromagnetic material. An annular surround 610 made from a resilient material, such as butyl rubber, has an outer perimeter portion 611 and an inner perimeter portion 613. The outer perimeter portion 611 is attached to the flange 603 of the annular stepped frame 602, while the inner perimeter portion 613 is attached to a cone disc 612, which integrates the cone and support ring of the previous embodiments. In a particular embodiment, the cone disc 612 is made from aluminum, which has the effect of reducing magnetic eddy currents during speaker operation. As a result, the low-profile speaker 600 operates more efficiently, i.e., requiring less power for the equivalent output when compared to the low-profile speaker 600 using a non-metallic cone disc 612. In an alternate embodiment, the cone disc 612 is made from a transparent material allowing for a clear view of the interior components of the speaker. In this case lights could be place behind the transparent surface of the cone disc to enhance the appearance of the low-profile speaker 600. Further the transparent material could be coated to allow for digital photographs or video to be shown on the surface of the cone disc 612.

A voice coil 614 is wound around a perimeter portion of the cone disc 612. One of skill in the art will recognize that the voice coil 614 could be integrated with the cone disc such that a single component could include the cone, support ring and voice coil shown in the embodiment of FIG. 2, for example.

Low-profile speaker 600 operates much like the embodiments described above. When fully assembled, there is a gap (not shown) between the top plate 608 and the vertical portion 615 of the pole piece 606. The voice coil 614 and the perimeter portion of the cone disc 612 are suspended in the gap, held in place by the surround 610. As can be seen from FIG. 11, the surround 610 has two arched portions rather than the one arched portion shown in the surround 108 of FIG. 2. With the larger surround 608 of FIG. 11, there is a more substantial attachment between the surround 608 and the cone disc 612. This provides greater support and stability to the cone disc 612 and voice coil 614.

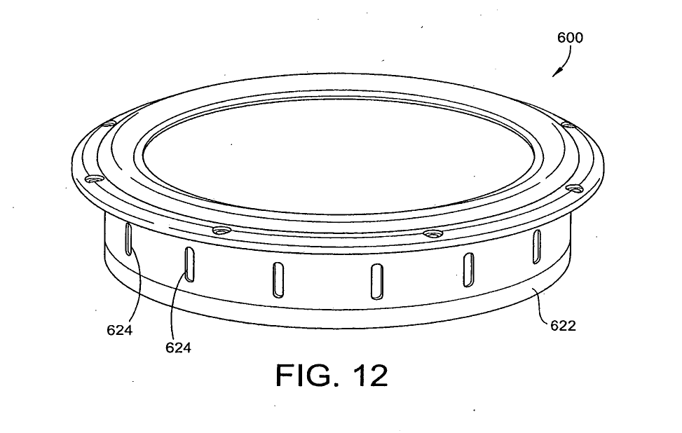

FIG. 12 shows an isometric view of low-profile speaker 600 assembled. In the embodiment of FIG. 12, speaker low-profile 600 includes a frame 622 with a plurality of slots 624 in a perimeter portion of the frame 622. In the embodiment shown, the slots are vertically oriented. The slots permit a cooling flow of air into and out of the low-profile speaker 600. In alternate embodiments, the slots 624 could be round holes, or otherwise suitably shaped openings to allow a flow of air through the speaker 600. In a further embodiment, the pole piece 606 may have a plurality of openings similar or identical to those in the frame 622. In addition to the cooling function, the plurality of slots 624 also reduces the back pressure inside the low-profile speaker 600 caused by movement of the cone disc 612 during speaker operation. This reduces the stress on slow-profile speaker 600 components. In conventional sealed speakers, it is common for back pressure to increase during speaker operation. While the embodiment of FIG. 12 shows that the low-profile speaker 600 and most components are round, other shapes, including, but not limited to, rectangular, hexagonal, octagonal, oval, and triangular are envisioned within the scope of the invention.

As shown in the attached drawings, exemplary embodiments of a miniature low-profile speaker and case assembly are disclosed herein. As will be described below, embodiments of the present invention exhibit better performance in the low audio frequency range than found on conventional miniature-sized speakers. While the embodiments of the miniature low-profile speaker and case assembly provided herein are described in terms of its use with a smartphone, the invention may be used in other applications, including other consumer electronic devices, or in other systems able to take advantage of the benefits provided by the invention. Many design aspects of the miniature low-profile speaker are disclosed in U.S. Patent Pub. No. 2013/0266173, filed on Dec. 23, 2011, the entire teachings and disclosure of which is incorporated herein by reference thereto.

As referenced above, a typical application for embodiments of the present invention is with respect to its application for smartphones, tablet computers, and the like. In a particular embodiment, the miniature low-profile speaker and case assembly is sized to accept a smartphone, and includes an integral connector, such as a USB connection or proprietary device connection. The integral connector is typically located at a bottom end of the rectangular case assembly. The case assembly may be configured to supply power from the battery, via the connector, to operate or charge the handheld electronic device. In some embodiments, this function may only be executed when the charge on the handheld electronic device battery drops below some threshold level.

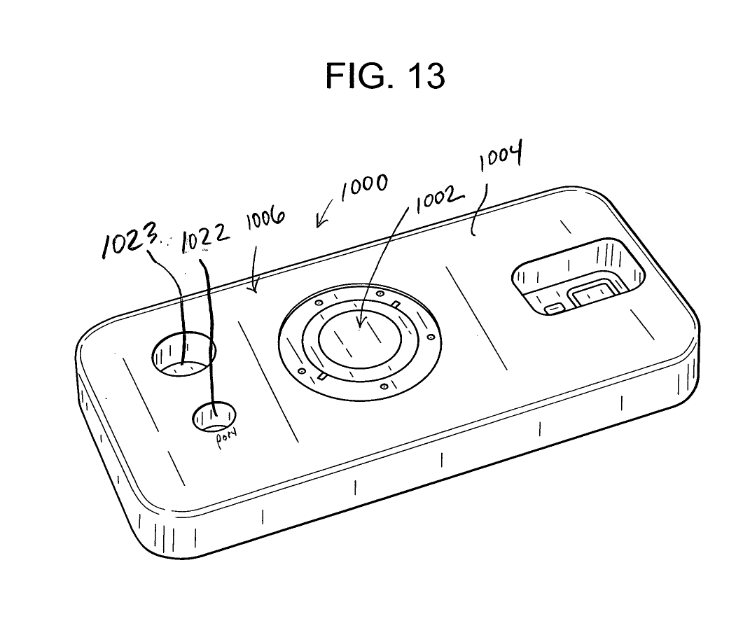

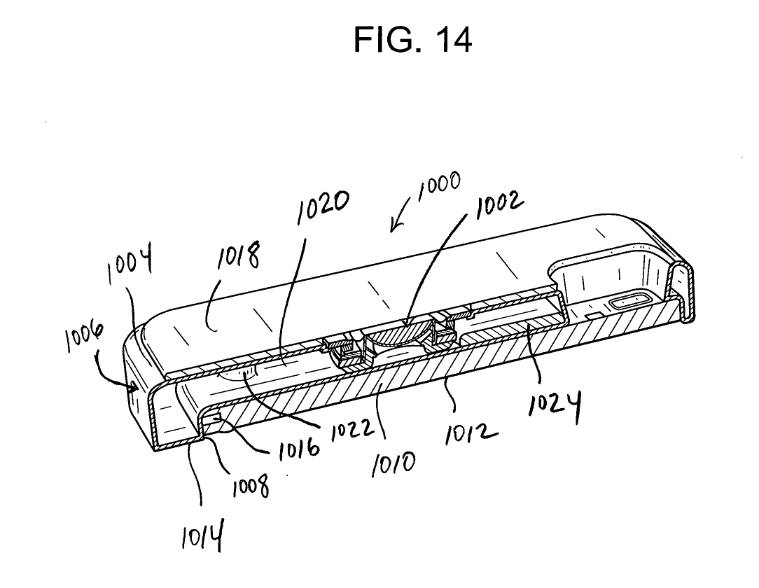

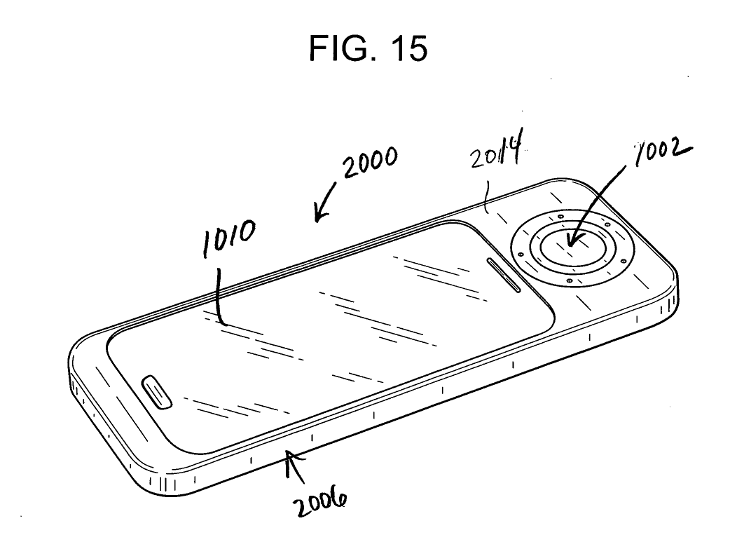

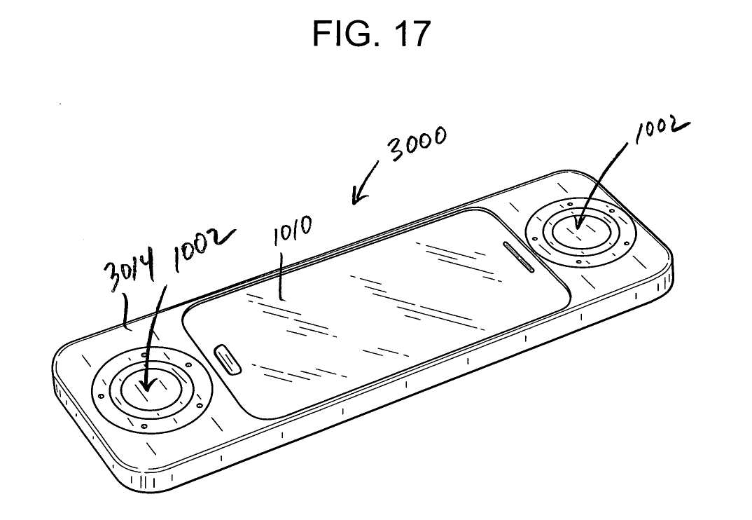

FIGS. 13-18 show different embodiments of the case assembly. Specifically, FIG. 13 is a perspective view of a case assembly 1000 wherein a low profile speaker 1002 is provided on a back 1004 of the case assembly, FIG. 15 is a perspective view of a case assembly 2000 wherein a low profile speaker 2002 is provided on a front 2004 of the case assembly 2000, and FIG. 17 is a perspective view of a case assembly 3000 wherein two low profile speakers 3002, 3004 (preferably, one for the right channel and one for the left channel) are provided on a front 3006 of the case assembly 3000. FIGS. 14, 16 and 18 are cross-sectional views of each of these three embodiments.

The embodiment shown in FIGS. 13 and 14 will first be described in detail, and then the remaining embodiments will be described mainly just pointing out the differences.

As shown in FIGS. 13 and 14, the case assembly 1000 includes a housing 1006 which includes a receptacle 1008 which is configured to receive and engage an electronics device 1010, such as a smartphone. The case assembly 1000 is configured to mechanically engage the electronics device 1010 such that electronics device 1010 is securely retained in the receptacle 1008, preferably such that when the electronic device 1010 is retained in the receptacle 1008, a front surface 1012 of the electronics device 1010 is generally flush with a front surface 1014 of the case assembly 1000. Additionally, the case assembly 1000 is configured to electronically engage the electronics device 1010 via a connector 1016 in the receptacle 1008. The connector 1016 may be, for example, a connector which is configured to engage an iPhone or other smartphone, such that case assembly 1000 receives a digital signal from the electronics device.

As shown, preferably the low profile speaker 1002 is mounted generally flush with the back 1004 of the housing 1006. As shown in FIG. 14, the case assembly 1000 may include a protective grill/cover 1018 which covers and protects the speaker 1002. Inside the housing 1006 is a chamber 1020 which is configured, sized and shaped to match the speaker 1002 and maximize its audio output. The housing 1006 may also be provided with a port 1022 and pass-through 1023 to enhance the sound heard by the user. Specifically, the pass-through 1023 provides that the speaker 1002 located in the back side of the smartphone can transmit sound to the front side of the housing 1006.

Disposed in the housing 1006 is a battery and electronics package 1024, wherein the battery and electronics package 1024, collectively, is electronically connected to the connector 1016 in the receptacle 1008.

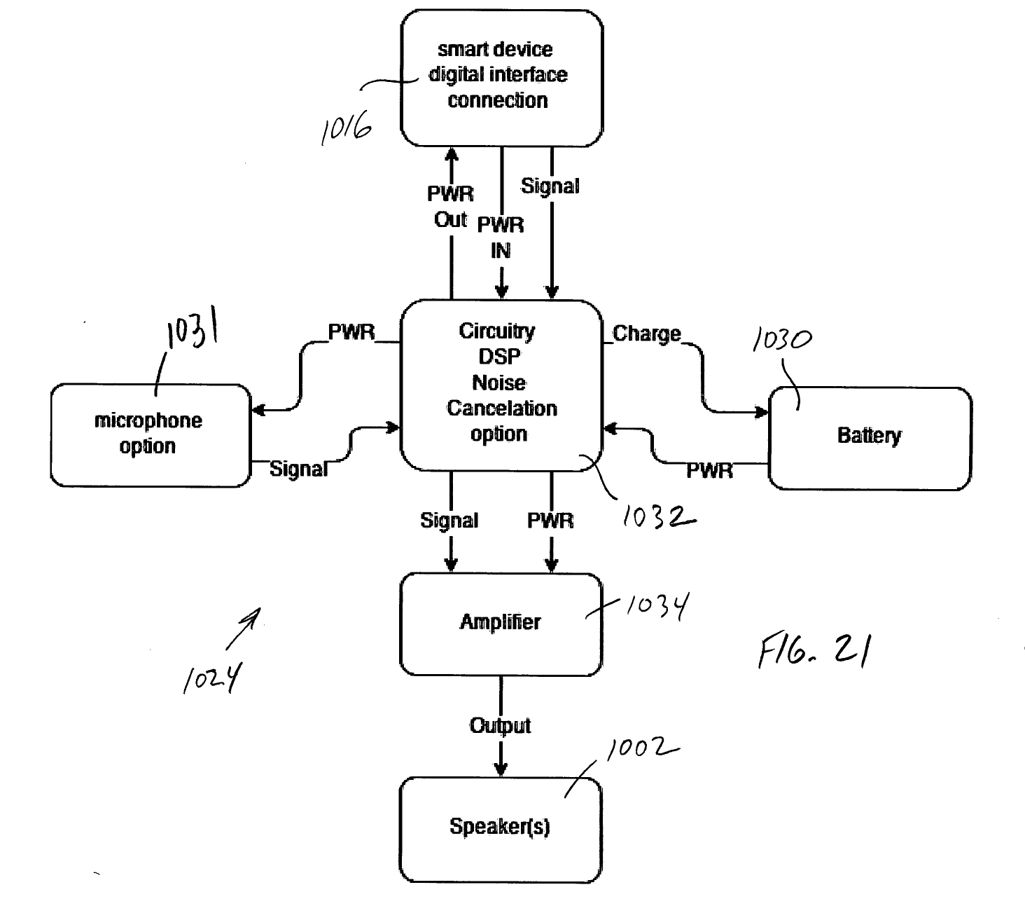

A block diagram of an exemplary battery and electronics package 1024 which can be used illustrated in FIG. 21. FIG. 21 is applicable to any of the embodiments shown in FIGS. 13-18. As shown, the package includes a battery 1030 (preferably rechargeable, in which case an interface (not specifically shown) would be provided on an exterior surface of the case assembly for engagement with a charger), a digital signal processor 1032, and an amplifier 1034. The battery 1030 powers the miniature low-profile speaker(s) 1002, and also preferably provides secondary power to the electronics device 1010 (via connector 1016). The digital signal processor 1032 is preferably configured to detect a level of ambient noise surrounding the case assembly 1000 (such as by using one or more microphones 1031) so that a user is always able to hear the output of the low-profile speaker 1002. The digital signal processor 1032 may be configured to automatically set the volume from the low-profile speaker 1002 at a level above that of the ambient noise.

Typically all handheld electronic devices include a speaker, though not usually of the highest quality. Embodiments of the present invention include a low-profile speaker and case assembly configured to provide sound to complement sound provided by a speaker in the handheld electronic device, such that the combined speakers produce a full range of frequency cross-over up to 20 kilohertz. In this way, the speaker in the handheld electronic device may only provide sound in the frequency range where it is most efficient. The low-profile speaker of the present invention may provide low-frequency sounds that are typically not reproduced very well by the handheld electronic device speaker.

In a particular embodiment, the amplifier is a three watt rms amplifier, and the driver for the speaker has a diameter ranging from 30-40 millimeters, and a depth ranging from 8-12 millimeters. Proximate the driver, the internal chamber of the housing is sized, shaped and configured to optimize the performance of the speaker and case assembly.

In certain embodiments, the interface housing is spaced from the outer housing in order to provide at least two millimeters of clearance above the cone of the driver to allow for movement thereof. The outer housing in the proximity of the miniature speaker may have a plurality of small holes to allow for sound transmission through the outer housing. When a smartphone is inserted into the case assembly, the interior volume, or back volume, typically ranges from 70 to 100 cubic centimeters.

In contrast to conventional speakers of approximately the same size, which typically have resonance frequencies ranging from 700 to 900 hertz, embodiments of the miniature low-profile speaker described herein have resonance frequencies under 200 hertz. The miniature low-profile speaker may feature an integrated voice coil and cone assembly having a thin-walled cone which is stiffened and supported by a foam material, a polyurethane foam for example. The foam also serves as the adhesive to securely attaché the voice coil to the cone such that the assembly can be positioned inside a U-shaped magnetic pole piece assembly, for example. In a particular embodiment, the integrated voice coil and cone assembly is connected to a surround on the front side, and to a spider on the back side.

The surround and the spider are made from a resilient material to allow for movement of the driver during speaker operation. The range of movement of the driver is called the “excursion”. A maximum excursion may be defined as the maximum controlled movement, in one direction, of the voice coil and cone assembly into the U-shaped magnetic pole piece assembly. Embodiments of the driver for the miniature low-profile speaker having varying diameters have a depth of no more than one quarter of an inch, though driver depths greater and lesser than one quarter inch are contemplated. Such a miniature speaker may have an internal case volume is tuned to the resonance frequency of the system.

FIGS. 15-18 illustrate alternative embodiments of the case assembly shown in FIGS. 13-14. In FIGS. 15-18 many of the same reference numbers that were previously used in FIGS. 13 and 14 are used. This is because the components are similar or identical.

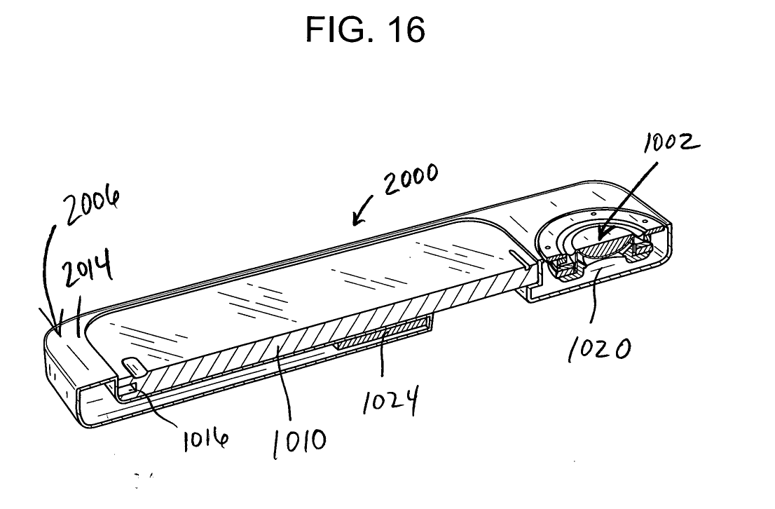

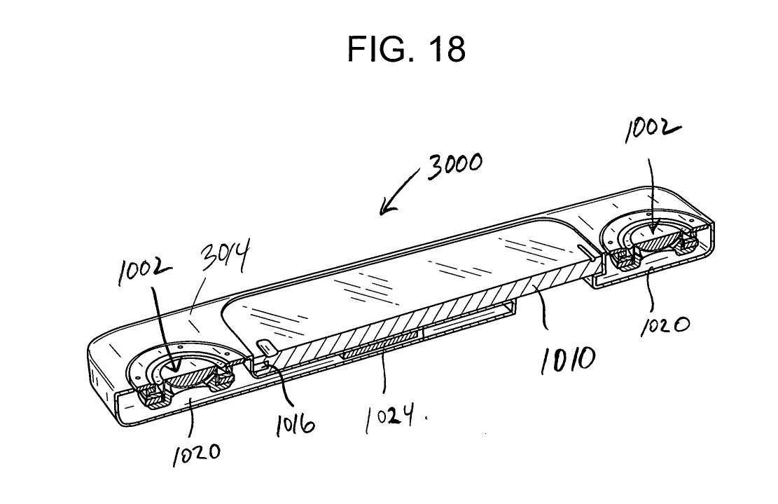

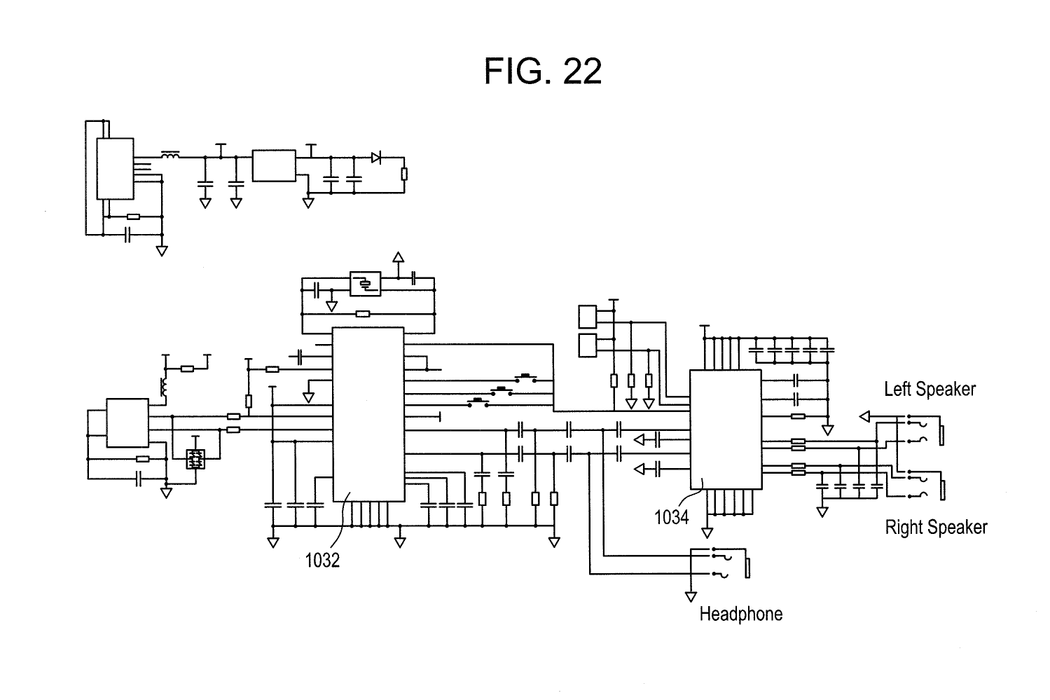

The case assembly 2000 shown in FIGS. 15-16 is very much like the case assembly 1000 shown in FIGS. 13 and 14, but provides a speaker 1002 on the front 2014 of the housing 2006 rather than the back. The case assembly 3000 shown in FIGS. 17-18 is very much like the case assembly 1000 shown in FIGS. 15 and 16, but provides two speakers 1002 on the front 3014 of the housing (preferably one speaker for the right channel of a stereo signal, and another speaker for the left channel of a stereo signal). This particular embodiment effectively converts an electronics device, such as a smartphone, into a miniature stereo boom box. To this end, the digital signal processor 1032 would preferably be somewhat different than would be provided for the case assemblies previously-described which have one speaker, and a circuit diagram of the overall circuit could appear as shown in FIG. 22.

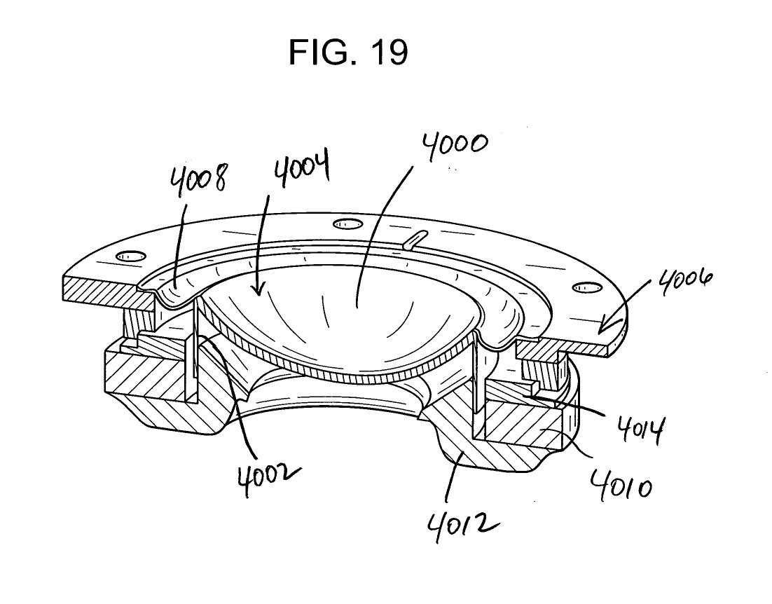

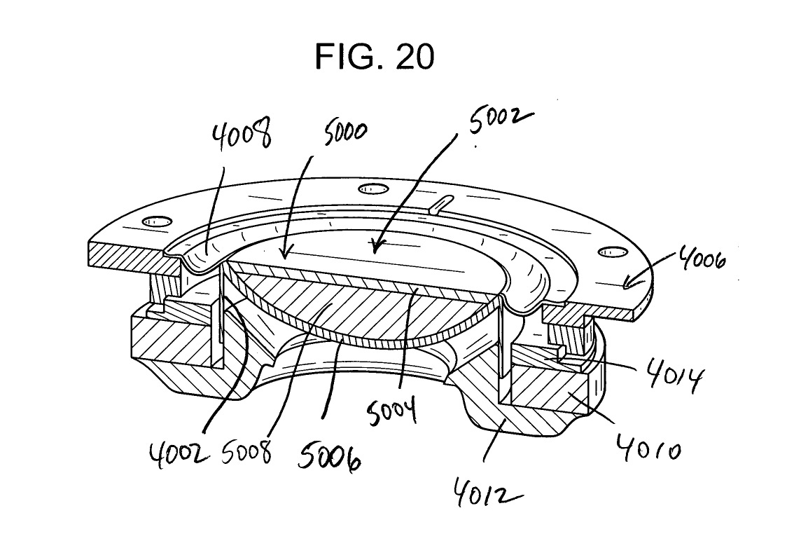

FIG. 19 is a cross-sectional view of one version of the low profile speaker which can be used in connection with the case assemblies shown in FIGS. 13-18, while FIG. 20 is a cross-sectional view of another version of the low profile speaker which can be used in connection with the case assemblies shown in FIGS. 13-18.

The speaker shown in FIG. 19 provides a dished diaphragm 4000 which is integral with a voice coil 4002, thereby providing an integrated voice coil diaphragm 4004. The speaker includes a frame 4006, and the dished diaphragm 4000 is connected to the frame 4006 via a surround 4008 which is attached to both the diaphragm 4000 and the frame 4006. The speaker includes a magnet 4010 which is disposed between a pole piece 4012 and a top plate 4014, and the voice coil 4002 is suspended between the pole piece 4012 and the magnet 4010, and is driven by an amplifier 1034 of the circuit.

The speaker shown in FIG. 20 is very much like the speaker shown in FIG. 19, except that the integrated voice coil diaphragm 5000 provides a flat diaphragm 5002 rather than a dished diaphragm, and the diaphragm overall is much thicker. Preferably, the diaphragm 5002 comprises a top layer 5004 formed of thermoplastic, a bottom skin 5006, and structural foam 5008 disposed under the plastic top layer 5004, filling the concave dome and bonding same to the remainder of the integrated cone.

Many different embodiments of speaker have been described herein and shown in the drawings, and still more versions are disclosed and described in the two provisional applications which have been incorporated herein by reference. Any of the speakers disclosed can be used as the speakers in the case assemblies shown in FIGS. 13-18. Additionally, a method such as is disclosed in U.S. Provisional Application Ser. No. 62/112,535 can be used to make the speaker.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A case assembly comprising:
a housing having a receptacle which is configured to mechanically and electronically engage a handheld electronic device;
an amplifier in the housing;
a digital signal processor in the housing connected to the amplifier, the digital processor configured to receive digital signals from the handheld electronic device;
a battery in the housing, supplying power to the digital signal processor and the amplifier; and
at least one speaker on the housing, connected to the amplifier, and powered by the battery.

2. The case assembly of claim 1, wherein the at least one speaker has a resonance frequency below 200 hertz.

3. The case assembly of claim 1, wherein the digital signal processor is configured to tune to output of the at least one speaker.

4. The case assembly of claim 1, wherein the at least one speaker comprises an integral voice coil and cone assembly.

5. The case assembly of claim 1, further comprising a connector in the receptacle for electrically coupling the handheld electronic device to the case assembly.

6. The case assembly of claim 1, wherein the case assembly is configured to supply power, via the battery, to operate or charge the handheld electronic device which is in the receptacle.

7. The case assembly of claim 1, wherein the at least one speaker is configured to provide sound to complement sound provided by the handheld electronic device, such that the at least one speaker and the handheld electronic device produce a full range of frequency cross-over up to 20 kilohertz.

8. The case assembly in claim 1, wherein the digital signal processor is configured to detect a level of ambient noise surrounding the case assembly, and is further configured to automatically set a volume from the at least one speaker at a level above that of the ambient noise.

9. The case assembly of claim 1, further comprising a noise cancellation circuit which is configured to maximize clarity of audio produced by the case assembly.

10. The case assembly in claim 1, wherein the housing comprises a rear surface, and wherein the at least one speaker is disposed on the rear surface.

11. The case assembly in claim 1, wherein the housing comprises a front surface, wherein said receptacle is provided on the front surface, and wherein the at least one speaker is disposed on the front surface.

12. The case assembly in claim 1, wherein the housing comprises a front surface, wherein said receptacle is provided on the front surface, and wherein the at least one speaker comprises two speakers which are disposed on the front surface.

13. The case assembly in claim 12, wherein the two speakers comprises a first speaker configured to output a right channel of a stereo signal, and a second speaker configured to output a left channel of the stereo signal.

14. The case assembly in claim 1, further comprising at least one microphone which the digital signal processor uses to perform noise cancellation.
